(19) United States
(12) Patent Application Publication
(10) Pub. No.: US 2025/0392102 A1
(43) Pub. Date: Dec. 25, 2025

(54) INTEGRATED RESONANTLY-COUPLED DUAL-WAVELENGTH TUNABLE EXTERNAL CAVITY LASER

(71) Applicant: Raytheon Company, Tewksbury, MA (US)

(72) Inventor: David Byron Borlaug, Harbor City, CA (US)

(21) Appl. No.: 18/752,206

(22) Filed: Jun. 24, 2024

(51) Int. Cl. H01S 5/14; H01S 5/10

(52) U.S. Cl. CPC H01S 5/142; H01S 5/101; H01S 5/1021

(57) ABSTRACT

An Integrated Resonantly-Coupled Dual-Wavelength Tunable External Cavity Laser is achieved using a common resonator and two or more independent resonators to select the two laser wavelengths. The resonators are present within the laser’s cavity, so no external frequency offset locking is required. The lasers are intrinsically frequency offset locked through the common resonator. The architecture achieves frequency offset locking by monitoring and controlling low-speed signals, greatly reducing the cost, size, weight, and power of comparable locking approaches. The laser provides broadband locking, because locking is achieved in the optical domain, without the need for high-frequency electronics. A 5-resonator architecture can enable finely resolved frequency offset tuning, as required for many RF downconverter applications using broadband reflective optical amplifiers.

### TECHNICAL FIELD

This disclosure relates generally to lasers. More specifically, this disclosure relates to an integrated resonantly-coupled dual-wavelength tunable external cavity laser.

### BACKGROUND

Frequency locked lasers, wherein a first laser emits light at a first frequency, and a second laser emits light at a second frequency, wherein the second frequency is at a specified frequency offset from the first laser, are utilized broadly in many systems including radio frequency (RF) photonic downconverters. Tunable lasers are susceptible to frequency drift, which in turn results in drifting between the frequency offset (frequency difference) between the first frequency and second frequency. Where the first and second lasers are part of a downconverter, the aforementioned drift in frequency offset manifests as frequency smearing or noise, which can limit system performance.

While frequency drift between the outputs of a pair of tunable lasers can be managed with active feedback systems, at a minimum, such approaches introduce size, weight, and power (“SWaP”) penalties associated with the additional circuitry for detecting and correcting drifts in frequency offset. Further, the componentry for actively detecting and correcting frequency drifts can introduce latency, spurs and other inaccuracies degrading performance. For example, the maximum frequency over which the two lasers’ phase noise can be locked is directly limited by the control loop latency. Additionally, the control circuitry can introduce spurs in the phase noise offset.

Thus, achieving frequency locking between two or more tunable lasers without incurring the weight, power and performance penalties remains a source of technical challenges and opportunities for improvement in the art.

### SUMMARY

This disclosure relates to an integrated resonantly-coupled dual-wavelength tunable external cavity laser.

In a first embodiment, a laser includes a common resonator, having a first free spectral range, a first resonant path comprising a first optical amplifier, the common resonator, a second resonator having a second free spectral range, and a mirror and a second resonant path comprising a second optical amplifier, the common resonator, a third resonator having a third free spectral range, and a second reflective mirror. The first resonant path is resonantly coupled to the second resonant path via the common resonator. The first resonant path lases at a frequency corresponding to a coincidence between a transmission window of the common resonator and the second resonator. The second resonant path lases at a frequency corresponding to a coincidence between a transmission window of the common resonator and the third resonator.

In a second embodiment, a method of making a laser includes providing a common resonator, having a first free spectral range, providing a first resonant path comprising a first optical amplifier and a second resonator having a second free spectral range and providing a second resonant path comprising a second optical amplifier and a third resonator having a third free spectral range. The first resonant path is resonantly coupled to the second resonant path via the common resonator. The first resonant path lases at a frequency corresponding to a coincidence between a transmission window of the common resonator and the second resonator. The second resonant path lases at a frequency corresponding to a coincidence between a transmission window of the common resonator and the third resonator.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIGS. 1A through 1C illustrate an example of a single-wavelength tunable laser which can be a foundational component of a resonantly-coupled dual-wavelength tunable laser according to embodiments of this disclosure;

FIGS. 2A through 2D illustrate examples of resonantly-coupled dual-wavelength tunable laser according to this disclosure;

FIGS. 3A through 3C illustrate a further example of a resonantly-coupled dual-wavelength tunable laser according to this disclosure; and

FIG. 4 illustrates operations of an example method for making a resonantly-coupled dual-wavelength tunable external cavity laser according to this disclosure.

### DETAILED DESCRIPTION

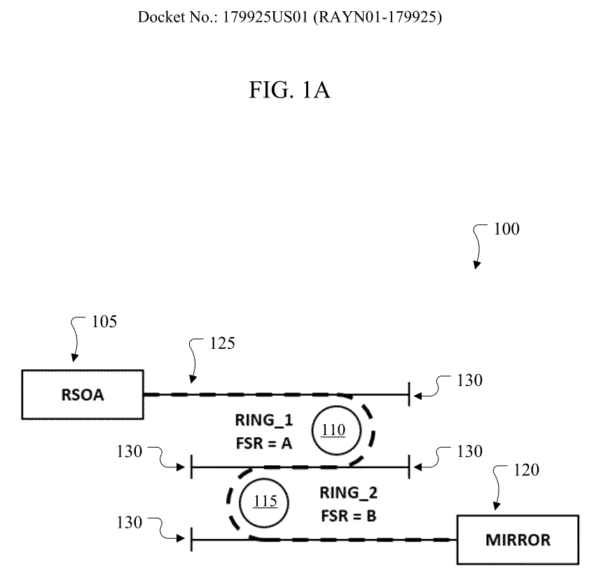

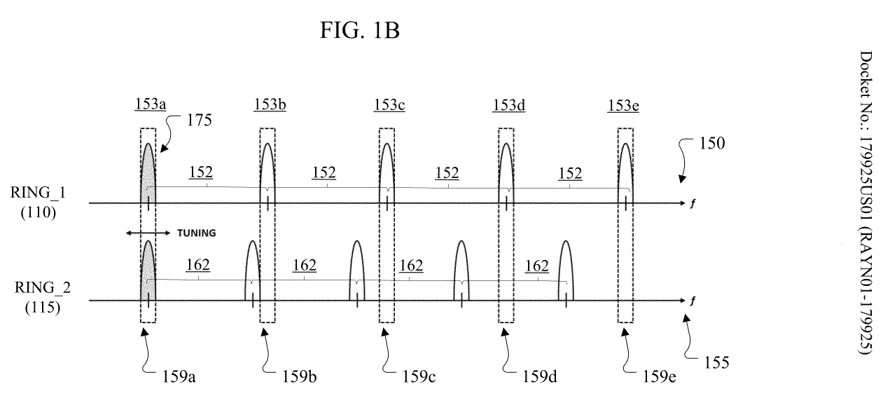

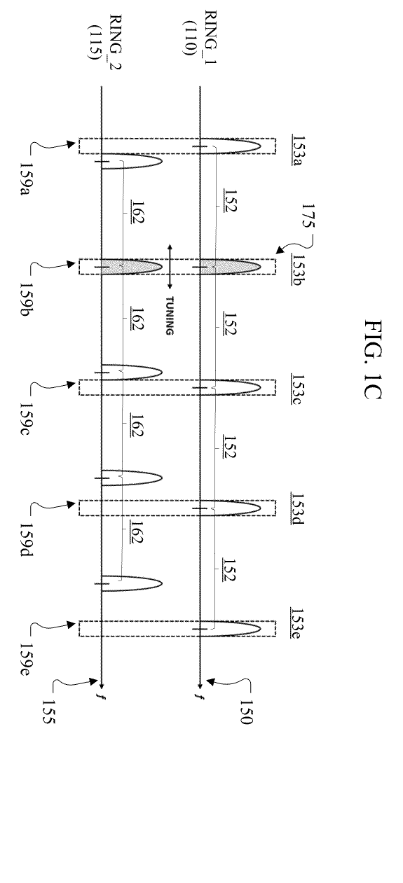

FIGS. 1A through 4 described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

Various aspects related to lasers, and more specifically to integrated resonantly-coupled dual-wavelength tunable cavity lasers are described. In one embodiment, a first laser cavity comprises a first reflective optical amplifier, a common resonator, a first resonator, and a first mirror; and a second laser cavity is comprised of a second reflective optical amplifier, the same common resonator, a second resonator, and a second mirror. The first laser cavity and the second laser cavity are both coupled to the same common resonator. The first and second laser cavities lase at a frequency corresponding to the coincidence between: the resonant transmission of the first resonator and the common resonator, and the resonant transmission of the second resonator and the common resonator; respectively. The first and second laser wavelengths are both resonant with the common resonator. Thus, both lasers are resonantly coupled to the same common resonator. Resonant coupling to the same common resonator intrinsically achieves frequency offset locking without complex electronics. Frequency offset locking is achieved in multiples of the common resonator’s free spectral range (FSR). The FSR is determined by the group velocity of the resonator, which is more stable against perturbation than the phase velocity, improving frequency offset locking stability.

In some embodiments the first resonator of the first laser cavity is instead replaced by two resonators; and the second resonator of the second laser cavity is instead replaced by yet another two resonators. In some such embodiments, the first laser cavity is comprised of a first reflective optical amplifier, a common resonator, a first resonator, a second resonator, and a first mirror; and a second laser cavity is comprised of a second reflective optical amplifier, the same common resonator, a third resonator, a fourth resonator, and a second mirror. The first and second laser cavities lase at a frequency corresponding to the coincidence between: the resonant transmission of the first resonator, the second resonator and the common resonator; and the resonant transmission of the third resonator, fourth resonator and the common resonator; respectively. Each laser cavity contains the common resonator, which is responsible for frequency offset locking. In the second embodiment, each laser cavity contains two resonators to enable non-degenerate lasing across a wide gain bandwidth while achieving finely resolved frequency offset locking.

FIGS. 1A through 1C illustrate an example of a single-wavelength tunable laser 100 which can be a foundational component of a resonantly-coupled dual-wavelength tunable laser according to embodiments of this disclosure. For consistency and convenience of cross-reference, elements common to both FIGS. 1A and 1C are numbered similarly.

Referring to FIG. 1A, a single-wavelength tunable laser 100 is comprised of a reflective semiconductor optical amplifier (RSOA) 105, a first resonator (RING_1) 110 with a free-spectral range (FSR) equal to A, a second resonator (RING_2) 115 with an FSR equal to B, and mirror (MIRROR) 120. As shown in FIG. 1A, RSOA 105 is connected along resonant path 125 to a RING_1 110, which is connected to RING_2 115, which is connected to the mirror 120. RING_1 110 and RING_2 115 can be ring waveguides in an external cavity (i.e., disposed on a separate portion of a common chip or common substrate from a gain medium). MIRROR 120 can be partially reflective, allowing a portion of the resonating laser power to exit the cavity and be utilized as the laser output. Examples of frequency selective ring technology includes p-i-n doped silicon ring resonators and thermally tuned silicon nitride ring resonators, in which the resonant wavelength of each of first frequency selective ring 110 and second frequency selective ring 115 can be tuned by applying electrical currents or voltages.

In this example, RING_1 and RING_2 are configured as ADD/DROP filters such that only light that is resonant with the rings continues on path 125. Non-resonant light follows the straight waveguide past the ring where it is extinguished at waveguide termination 130. Therefore, due to the Vernier effect, only light that is resonant with RING_1 and RING_2 may propagate along the portion of path 125 from RSOA to MIRROR. FIG. 1B illustrates aspects of the Vernier effect which is characteristic of single frequency tunable laser 100. In FIG. 1B, a first plot 150 shows the transmission spectrum of RING_1 110 expressed in terms of transmission amplitude versus frequency. As shown in the figure, RING_1 110 resonates, or has periodic amplitude peaks at a plurality of frequencies (for example, frequencies 153a, 153b, 153c, 153d through 153e). The frequency difference between each adjacent resonance is known as the free spectral range (FSR). For RING_1 110 the FSR 152 is indicated in FIG. 1B. Similarly, the FSR 162 for RING_2 is shown in second plot 155.

Single-frequency tunable laser 100 only lases at the frequencies where both RING_1 110 and RING_2 115 are transmissive. In the example of FIG. 1B, this coincidence occurs at 153a, the co-resonant frequency 175. Two resonators that have different FSRs will have a few or one coincidences (or co-resonances) between their transmissive frequencies. These co-resonances define a transmission window for the two resonators. By designing the FSR of RING_1 110 and RING_2 115 appropriately, it can be assured that only one co-resonance can occur within the gain bandwidth of RSOA 105 to achieve single frequency lasing.

As shown in FIG. 1C, the co-resonant frequency 175 can be tuned to 153b by shifting the transmission spectrum of RING_2 115. More generally, the co-resonant frequency 175 can be tuned continuously by shifting the transmission spectrum of RING_1 110 and RING_2 115.

However, the ability to precisely maintain the laser output frequency is challenged by frequency drift, wherein the value of co-resonant frequency 175 fluctuates over time due to confounding factors, including, without limitation, changes in temperature and the buildup of charge and heat. Thus, to maintain the laser output frequency 175 at a selected value, a feedback loop for measuring the laser frequency 175 and modulating the electrical currents supplied RING_1 110 and RING_2 115 is required. Skilled artisans will appreciate that measuring and implementing active control of the co-resonant frequency 175 requires additional circuitry and necessarily imposes size, weight, and power (“SWaP”) penalties on the system. Further, where the apparatus for providing active control of co-resonant frequency 175 relies on a digital processor, this can introduce further challenges associated with processor latency and rounding errors.

Skilled artisans will further appreciate the aforementioned technical challenges and SWaP penalties associated with implementing active frequency control for a single tunable frequency laser are compounded when trying to actively control the outputs of two tunable frequency lasers such that the output of a second laser is frequency locked to the output of a first laser. As used in this disclosure, the expressions “frequency offset locked” or “frequency locked” refers to the condition where the frequency difference between two lasers is locked or held constant.

For many applications, including, without limitation, optical downconverters, loss of frequency locking degrades overall system performance. Therefore, achieving and maintaining a frequency offset locking between two or more tunable lasers comprises a primary design objective.

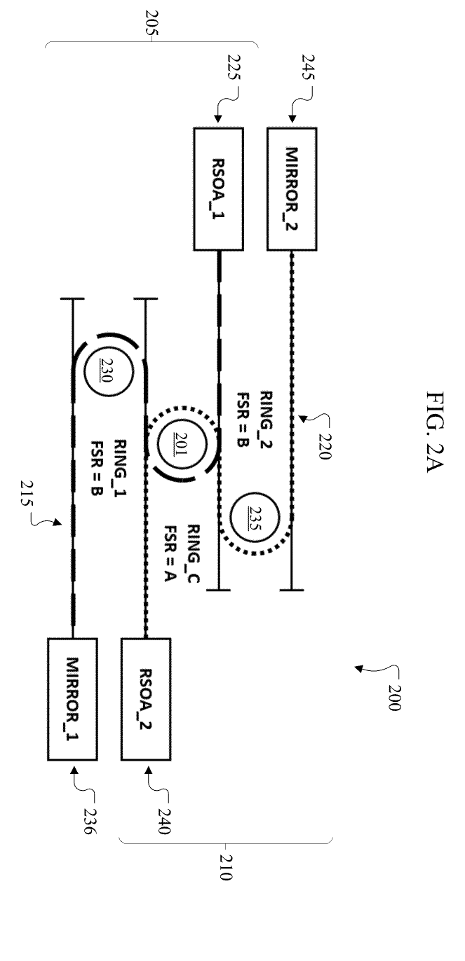

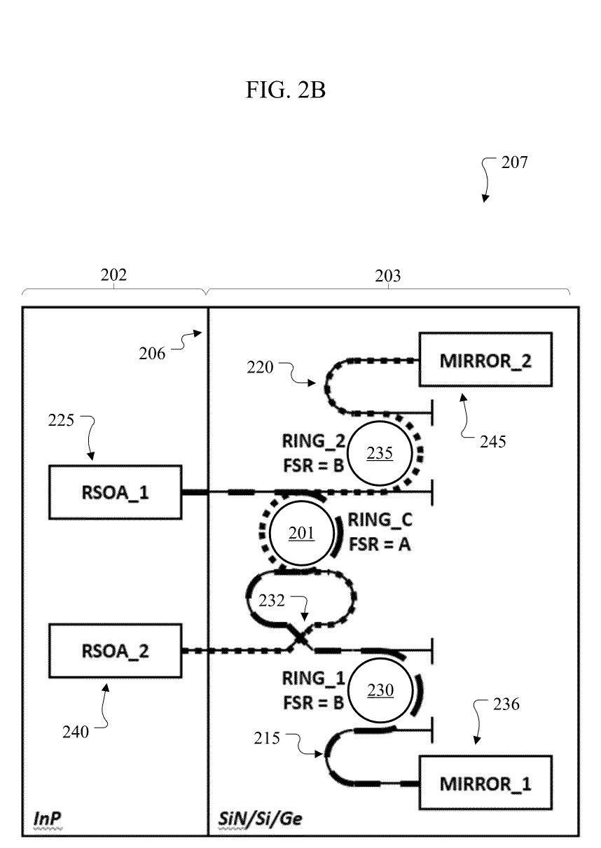

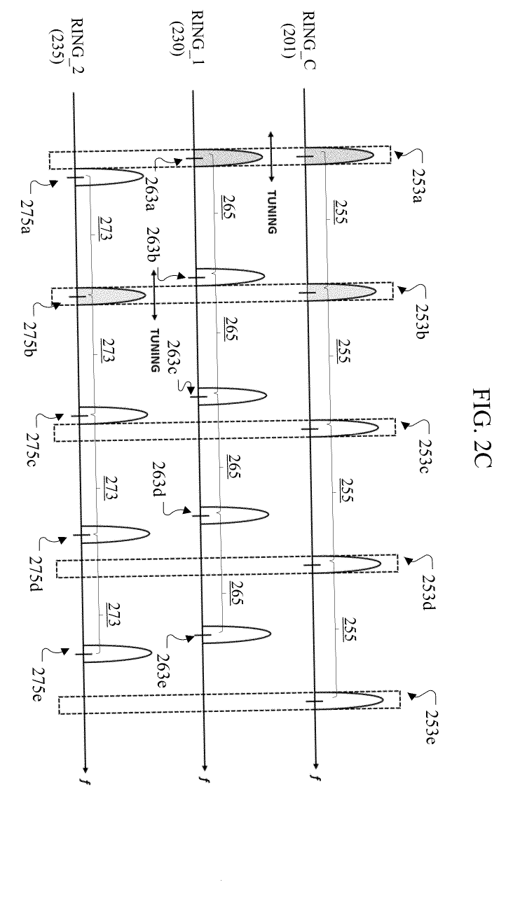

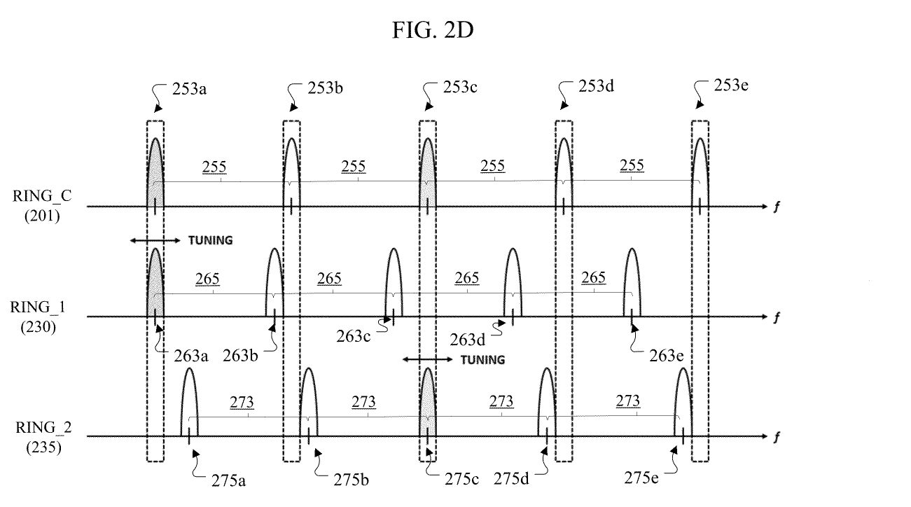

FIGS. 2A through 2D illustrate an example of a resonantly-coupled dual-wavelength tunable laser according to this disclosure. For consistency and convenience of cross-reference, elements common to more than one of FIGS. 2A through 2D are numbered similarly. Referring to FIG. 2A, a resonantly-coupled dual-wavelength tunable laser 200 is comprised of: a first laser and second laser. The first laser is comprised of a first reflective semiconductor optical amplifier (RSOA_1) 225, a common resonator (RING_C) 201 with an FSR equal to A, a first resonator (RING_1) 230 with an FSR equal to B, and first mirror (MIRROR_1) 236 connected along resonant path 215 (bold dashed line). The second laser is comprised of a second reflective semiconductor optical amplifier (RSOA_2) 240, a common resonator (RING_C) 201 with an FSR equal to A, a second resonator (RING_2) 235 with an FSR equal to B, and second mirror (MIRROR_2) 245 connected along resonant path 220 (bold dotted line). In total, FIG. 2A depicts 3 resonators including the common resonator, RING_C 201. MIRROR_1 236 and MIRROR_2 245 can be partially reflective, allowing a portion of the resonating laser powers to exit the cavities and be utilized as the laser outputs.

Common resonator RING_C 201 can be a tunable frequency selective ring (for example, a p-i-n doped silicon ring resonator or a thermally tuned silicon nitride ring resonator) whose resonant frequency can be tuned through the application of electrical currents or voltages. Alternatively, common resonator RING_C 201 can be a non-tunable resonator. Regardless of tunability, common resonator RING_C 201 has a free spectral range A, wherein common resonator RING_C 201 is transmissive in an ADD/DROP filter configuration at frequencies separated by a common frequency difference. Common resonator RING_C 201 can be provided on a portion of a substrate that is external to a gain stage.

As shown in FIG. 2A, a resonantly-coupled dual-wavelength tunable laser 200 further comprises a first laser 205 and a second laser 210, wherein first laser 205 and second laser 210 are resonantly coupled via common resonator RING_C 201, to structurally enforce (i.e., without requiring active feedback-based control to mitigate the effects of frequency offset drift) frequency locking between two or more lasers. Referring to the illustrative example of FIG. 2A, first laser 205, second laser 210 and common resonator RING_C 201 define a first resonant path 215 (shown as a dashed path in the figure) and a second resonant path 220 (shown as a dotted path in the figure).

In this non-limiting example, first laser 205 can embody a similar construction to tunable laser 100 in FIGS. 1A and 1C, in that it employs a plurality of resonators connected by an external cavity to achieve a Vernier effect, wherein a non-degenerate (i.e., lasing at a single frequency without unwanted overtones) laser output at a first frequency is obtained. As shown in FIG. 2A, a first laser is comprised of a first reflective semiconductor optical amplifier (RSOA_1) 225, a common resonator (RING_C) 201 with an FSR equal to A, a first resonator (RING_1) 230 with an FSR equal to B, and first mirror (MIRROR_1) 236 connected along resonant path 215. First mirror (MIRROR_1) 236 can be partially reflective, allowing a portion of the resonating laser power to exit the cavity and be utilized as the first laser output.

Similarly, second laser 210 can embody a similar construction to tunable laser 100 in FIGS. 1A and 1C to obtain a non-degenerate laser output at a second frequency. As shown in FIG. 2A, second laser is comprised of a second reflective semiconductor optical amplifier (RSOA_2) 240, a common resonator (RING_C) 201 with an FSR equal to A, a second resonator (RING_2) 235 with an FSR equal to B, and second mirror (MIRROR_2) 245 connected along resonant path 220. Second mirror (MIRROR_2) 245 can be partially reflective, allowing a portion of the resonating laser power to exit the cavity and be utilized as the second laser output.

As noted previously in this disclosure, by concatenating ring resonators along first resonant path 215 and second resonant path 220, the wavelengths at which first laser 205 and second laser 210 lase are governed by the Vernier effect and limited to the narrow subset of wavelengths at which the resonant peaks of the frequency tunable rings and the common resonator 201 coincide. Because of this, the laser outputs at the first mirror (MIRROR_1) 236 and the second mirror (MIRROR_2) 236 are necessarily frequency locked to one another as common resonator (RING_C) 201 is part of both first resonant path 215 and second resonant path 220. The first and second laser wavelengths are both resonant with the common resonator. Thus, both lasers are resonantly coupled to the same common resonator. Resonant coupling to the same common resonator intrinsically achieves frequency offset locking without complex electronics. Frequency offset locking is achieved in multiples of the common resonator’s free spectral range (FSR). The FSR is determined by the group velocity of the resonator, which is more stable against perturbation than the phase velocity, improving frequency offset locking stability.

FIG. 2B illustrates a non-limiting example of a resonantly-coupled dual-wavelength tunable external cavity laser 207 embodied as a photonic integrated circuit (PIC) or multi-chip module (MCM). Laser 207 utilizes the architecture described with reference to FIG. 2A. As shown in FIG. 2B, the architecture is divided along a boundary 206 separating gain material 202, from an adjacent low optical loss external cavity material 203. Gain material 202 can, in some embodiments, without limitation, be a monolithically pattern gain material creating a single monolithic photonic integrated circuit (PIC) chip, or a patterned chip that contributes to a multichip module (MCM). For the purposes of FIG. 2B, a single monolithic photonic integrated circuit (PIC) chip would include the elements of gain material 202 and low optical loss material 203 on a single chip. For the purposes of FIG. 2B, a MCM would be the assembly of gain chip 202 with low optical loss chip 203. Gain material 202 can be indium phosphide (InP), gallium arsenide (GaAs) or any other suitable gain material. Low optical loss material 203 can be silicon (Si), silicon nitride (SiN), or any other suitable low optical loss material. Laser 207 of FIG. 2B is functionally the same as laser 200 of FIG. 2A. The addition of waveguide crossing 232 enables the architecture in FIG. 2A to be folded, as illustrated in FIG. 2B. The waveguide crossing 232 is required to enable MCM implementations of laser 207, where the placement of passive external cavity elements on a low optical loss rectangular chip 203 is separated from the placement of reflective optical semiconductor amplifiers on a rectangular optical gain chip 202. The waveguide crossing 232 is of sufficient port isolation such that first resonant path 215 and second resonant path 220, which both contain waveguide crossing 232 in FIG. 2B, are non-interacting in waveguide crossing 232.

FIG. 2B illustrates a PIC instantiation of laser 207. Other embodiments of laser 207 may replace the gain chip in the MCM with off-chip amplifiers. For example, fiber-based amplifiers such as erbium doped fiber amplifiers, or similar amplifiers, can be coupled to the external cavity chip 203 to produce a resonantly-coupled dual-wavelength tunable external cavity laser.

As is likely apparent from the figures, resonantly-coupled dual-wavelength tunable external cavity laser 207 is, for the purposes of limiting the frequencies at which each of first resonant path 215 and second resonant path 220 radiate or lase at, analytically equivalent to resonantly-coupled dual-wavelength tunable laser 200 in FIG. 2A. Waveguide crossing 232 is a non-interfering intersection, which does not affect which frequencies resonate along first and second resonant paths 215 and 220, nor does it affect the fact that the frequencies at which first resonant path 215 and second resonant path 220 must necessarily be frequency locked according to the FSR and transmissive peaks of common resonator RING_C 201 due to the fact that common resonator RING_C 201 is part of both resonant paths. As described elsewhere in this disclosure, the presence of a common resonator RING_C along a plurality of resonant paths structurally enforces frequency offset locking between the outputs of each resonant path of the plurality of resonant paths.

FIGS. 2C and 2D further illustrate how, in certain embodiments according to this disclosure, frequency locking between first resonant path 215 and the second resonant path 220 can be structurally enforced, and at the same time, frequency tuned.

Referring to the illustrative example of FIG. 2C, frequency plots showing the transmission spectra of common resonator RING_C 201, first resonator RING_1 230, and second resonator RING_2 235 are provided. As shown in the figure, common resonator RING_C 201 is transmissive in an add/drop configuration (i.e., has periodic transmissive peaks) at frequencies separated by FSR A 255 (for example, transmissive peaks 253a through 253e).

Similarly, and as shown in FIG. 2C, first resonator RING_1 230 is transmissive in an add/drop configuration (as shown by periodic transmissive peaks) at frequencies separated by FSR B 265 (for example, frequencies 263a through 263e). Because of the Vernier effect, first resonant path 215 only radiates at those frequencies where resonant peaks of common resonator RING_C 201 and the first resonator RING_1 230 coincide. In this example, the resonant peaks of common resonator RING_C 201 and first resonator RING_1 230 coincide once in FIG. 2C, at frequency 253a/263a. Thus, depending on the FSR of RING_C 201 and RING_1 230, the frequency of the radiating light obtained at MIRROR_1 236 will be at frequency 253a/263a.

Similarly, and as shown in FIG. 2C, second resonator RING_2 235 is transmissive in an add/drop configuration (as shown by periodic transmissive peaks) at frequencies separated by FSR B 273 (for example, frequencies 275a through 275e). Because of the Vernier effect, second resonant path 220 only radiates at those frequencies where resonant peaks of common resonator RING_C 201 and the second resonator RING_2 235 coincide. In this example, the resonant peaks of common resonator RING_C 201 and second resonator RING_2 235 coincide once in FIG. 2C, at frequency 253b/275b. Thus, depending on the FSR of RING_C 201 and RING_2 235, the frequency of the radiating light obtained at MIRROR_2 246 will be at frequency 253b/275b.

The frequencies at which each resonator is transmissive can be shifted without significant impact to the FSR. This is because the phase velocity is principally responsible for the absolute frequency location of the transmissive peaks, and the group velocity is principally responsible for the periodicity or FSR of the transmissive peaks. For example, by applying a voltage or current to the p-i-n structure or heater of second resonator RING_2 235, the absolute frequency location of the transmissive peaks (275a through 275e) can be shifted without significant impact to the FSR 273 of RING_2 235. The susceptibility and resilience to tuning of the phase and group velocity, respectively, enables tunable frequency offset locking without introducing frequency drift.

In the example of FIG. 2C common resonator RING_C 201 and second resonator RING_2 235 coincide in at frequency 253b/275b. The frequencies at which second resonator RING_2 235 is transmissive can be shifted by applying a voltage or current to the p-i-n structure or heater of second resonator RING_2 235. As shown in FIG. 2D, the absolute frequency location of transmissive peaks (275a through 275e) is shifted up in frequency, without change to the FSR 273 of RING_2 235. Frequency shifting to RING_2 has occurred until the coincidence between transmissive peak 253c of RING_C 201 and transmissive peak 275c of RING_2 235 is maximized, at which point the frequency of laser light obtained at MIRROR_2 246 will be at frequency 253c/275c. Here again, the resonantly coupled dual-wavelength laser 200 lases at frequencies which correspond exclusively to peaks in the common ring RING_C 201 transmission spectrum and are thus inherently frequency locked.

For applications in which frequency offset locking between two laser beams is a primary design objective, laser 200, can maintain a stable frequency offset lock better than systems which rely on frequency control to try and keep one laser’s output frequency locked to another’s. Drifts in the absolute frequency of one or more of resonators (common resonator RING_C 201, first resonator RING_1 230, or second resonator RING_2 235) of laser 200 do not impact the FSR 255 of RING_C 201 which is principally responsible for maintaining the frequency offset lock. Because FSR 255 and RING_C 201 is an intrinsic part of laser 200, frequency offset locking is an intrinsic part of laser 200, and no frequency control is required to accomplish frequency locking.

For example, in FIG. 2C, if the absolute frequency (253a through 253e) of common resonator RING_C 201 drifts over time, then the absolute frequency of RING_1 230 and RING_2 235 must be tuned to maintain coincidence between 253a & 263a, and 253b & 275b. The lasers output at MIRROR_1 236 and MIRROR_2 245 will also drift, but the difference between those frequencies, or the frequency offset, will remain locked.

Tuning can be accomplished monitoring and maximizing laser power, this minimizing cavity round trip loss and maximizing frequency coincidence. Importantly, the frequency offset lock is accomplished by one component, the common ring RING_C 201. There is no need to match the frequencies of two separate lasers or components. Tuning RING_C 201 is not necessary to achieve frequency offset locking, RING_1 230 and RING_2 235 can be tuned to RING_C 201, which further minimizes the potential for absolute frequency drifting of RING_C 201. Further, tuning of RING_C principally impacts the absolute frequency of RING_C’s 201 transmission peaks (253a through 253e) with minimal impact to the FSR 255 of RING_C, which is responsible for frequency offset locking, further minimizing the architecture’s susceptibility to frequency offset drift.

Similarly, if the absolute frequency of first resonator RING_1 230 or second resonator RING_2 235 drifts relative to common resonator RING_C 201, the transmission of RING_1 230 or RING_2 235 where it overlaps with common ring RING_C 201 may be lower, resulting in increased round trip cavity loss and lower laser output power. However, despite this, the laser outputs MIRROR_1 236 and MIRROR_2 245 will remain frequency locked to each other, and the diminished laser power can be readily corrected by tuning the resonators’ absolute frequency. This tuning method reduces SWaP by relying only on simple power measurement and power optimization. No frequency manipulation is required. No control loop latency must be reduced to improve the phase noise difference between the two frequency locked lasers, because the lasers a fundamentally resonant with each other through the common resonator RING_C 201. The control of the dual lasers, and performance of the offset frequency locking, is therefore improved and simplified.

While not shown in either FIGS. 2A through 2D, resonantly-coupled dual-wavelength tunable laser 200 can include one or more integrated photodiodes following the output of MIRROR_1 236 and MIRROR_2 245 to assist in tuning one or more of first resonator RING_1 230, second resonator RING_2 235, or common resonator RING_C 201.

While not shown in either FIGS. 2A through 2D, resonantly-coupled dual-wavelength tunable laser 200 can include one or more integrated wavemeters following the output of MIRROR_1 236 and MIRROR_2 245 to assist in tuning one or more of first resonator RING_1 230, second resonator RING_2 235, or common resonator RING_C 201. Integrated wavemeters may be utilized to add absolute frequency tuning to laser 200.

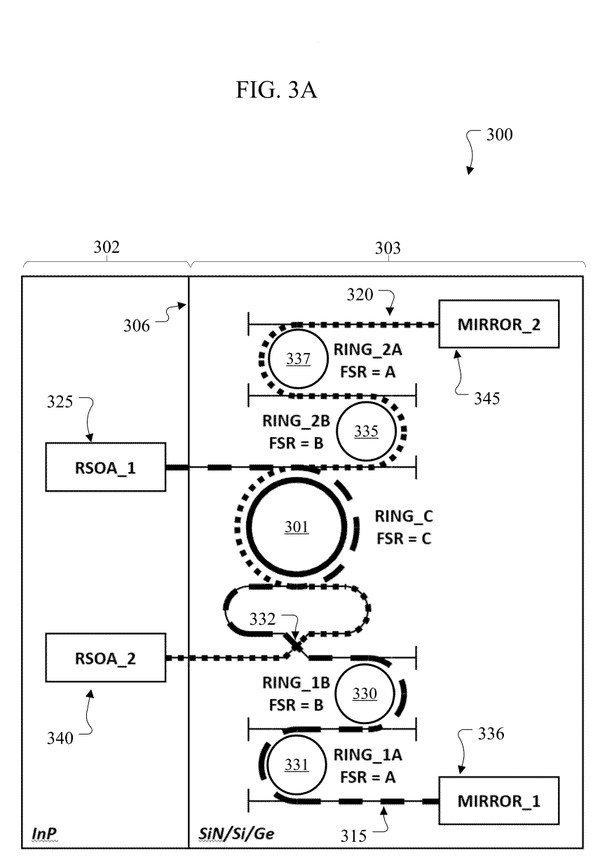

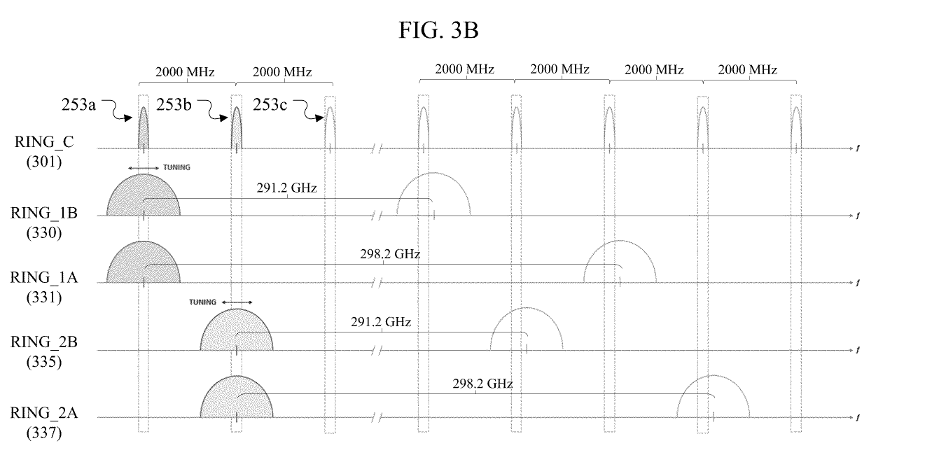

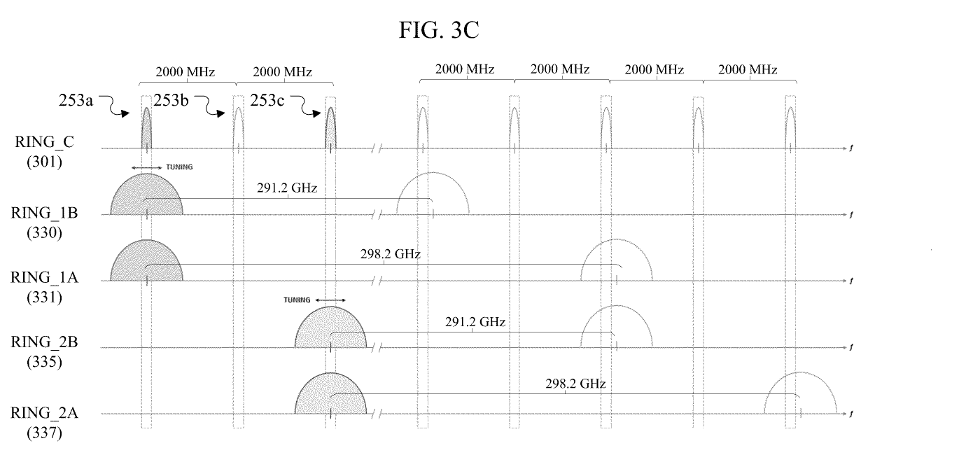

FIGS. 3A through 3C illustrate a further example of a resonantly-coupled dual-wavelength tunable laser 300 according to this disclosure. For consistency and convenience of cross-reference, elements common to more than one of FIGS. 3A through 3C are numbered similarly. Additionally, elements shown in FIGS. 3A through 3C previously described with reference to FIGS. 2A through 2D are numbered similarly.

FIG. 3A illustrates another example of a circuit embodying a resonantly-coupled dual-wavelength tunable external cavity laser 300, which builds upon the system described with reference to FIG. 2B by incorporating an additional frequency selective ring on each of first resonant path 315 (bold dashed line) and second resonant path 320 (bold dotted line).

Referring to FIG. 3A, a resonantly-coupled dual-wavelength tunable laser 300 is comprised of a first laser and second laser. The first laser comprises a first reflective semiconductor optical amplifier (RSOA_1) 325, a common resonator (RING_C) 301 with an FSR equal to C, a first resonator (RING_1B) 330 with an FSR equal to B, a second resonator (RING_1A) 331 with an FSR equal to A, and first mirror (MIRROR_1) 336 connected along resonant path 315 (bold dashed line). The second laser comprises a second reflective semiconductor optical amplifier (RSOA_2) 340, a common resonator (RING_C) 301 with an FSR equal to A, a third resonator (RING_2B) 335 with an FSR equal to B, a fourth resonator (RING_2A) 337 with an FSR equal to A, and second mirror (MIRROR_2) 345 connected along resonant path 320 (bold dotted line). In total, FIG. 3A depicts five resonators including the common resonator, RING_C 301. MIRROR_1 336 and MIRROR_2 345 can be partially reflective, allowing a portion of the resonating laser powers to exit the cavities and be utilized as the laser outputs.

An additional resonator is incorporated on both the first resonant path 315 and the second resonant path 320. For first resonant path 315, RING_1B 330 and RING_1A 331 have a sufficiently large FSR to ensure a single frequency transmission coincidence across the gain bandwidth of RSOA_1 325. Additionally, RING_1B 330 and RING_1A 331 have a sufficiently narrow full width at half maximum (FWHM) to enable first regime Vernier operation, where the laser sidemode suppression ratio is minimized. The inclusion of three resonators in first resonant path 315 alleviates the responsibility of RING_C 301 to have a large FSR and narrow FWHM. This allows the FSR of RING_C 301 to be greatly reduced, as is desirable for finely resolved tunable frequency offset locking. First resonant path 315 is therefore only transmissive when there is a coincidence between the transmission peaks of RING_C 301, RING_1B 330, and RING_1A 331. RING_2B 335 and RING_2A 337 accomplish the same objective for second resonant path 320.

FIGS. 3B and 3C illustrate example transmission spectra for resonantly-coupled dual-wavelength tunable external cavity laser 300. In this example, RING_1B 330 and RING_2B 335 have free spectral range B, while RING_1A 331 and RING_2A 337 have free spectral range A, and RING_C 301 has free spectral range C. As shown in FIG. 3B, as an example and without limitation, common resonator 301 has a free spectral range of 2000 MHz with a FWHM value of 175 MHz. Similarly, RING_1B 330 and RING_2B 335 have a free spectral range of 291.2 GHz, while rings RING_1A 331 and RING_2A 337 have a free spectral range of 298.2 GHz with each ring having a FWHM value of approximately 2500 MHz.

The FWHM of 2500 MHz (for tuning rings RING_1A, RING_1B, RING_2A & RING_2B) is less than twice the FSR of RING_C, 4000 MHz, minus the FWHM of RING_C, 175 MHz. Therefore, the FWHM of RING_C will overlap with only one tuning ring FWHM (RING_1A, RING_1B, RING_2A & RING_2B) when maximally coincident. The Vernier effect FSR produced by the combined tuning rings, RING_1A 331 and RING_1B 330, is sufficient to ensure a single non-degenerate laser frequency across a 50 nm gain bandwidth (FSR_A + FSR_B)/|FSR_A FSR_B|. The same gain bandwidth is supported for second resonant path 320, as RING_2A 337 and RING_2B 335 have the same FSR as RING_1A 331 and RING_1B 330. Three rings are minimally needed per resonant path to support finely resolved frequency offset locking (FSR_C < 2000 MHz) and single wavelength lasing across a 50 nm gain bandwidth. As shown by comparison between FIGS. 3B and 3C, the frequencies at which Vernier effect coincidences in the first and second resonant paths can be shifted by tuning RINGS 2A and 2B. For example, in FIG. 3B, the coincidences occur at transmissive peaks 353a and 353b. However, tuning to RING_2B and RING_2A can shift the coincidences to transmissive peaks 353a and 353c, as shown in FIG. 3C. Note that the frequency axis in FIGS. 3B and 3C is bifurcated to show that the large FSRs from RING_1A 331, RING_1B 330, RING_2A 337 and RING_2B 335 produce only two (2) laser frequency coincidences across a large gain bandwidth.

The examples described with reference to FIGS. 3A-3C are illustrative, rather than limitative, of embodiments according to this disclosure, which can be realized with additional, or different componentry. According to certain embodiments, the common resonator can be embodied using a spiral waveguide, one or more tunable optical couplers, and a phase shifter. Additionally, skilled artisans will appreciate that the frequency values described in the examples of FIGS. 3A-3C are illustrative, rather than limitative of the free spectral ranges and full width half maximums that could be used in embodiments according to this disclosure.

In certain embodiments, the mirrors bounding the ends of the resonant paths can be tunable loop mirrors where the portion of circulating light exiting the laser cavity can be tuned. While the examples provided by FIGS. 2A through 3C are described with reference to specific materials and wavelengths, these are for illustration and explanation only.

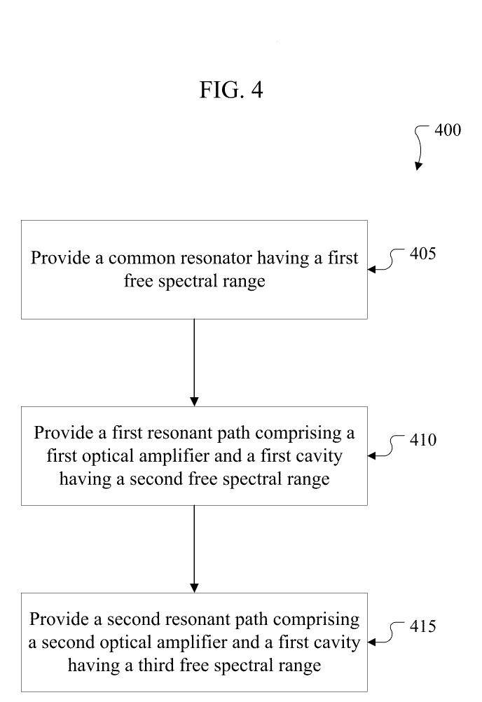

FIG. 4 illustrates operations of an example method 400 for making a resonantly-coupled dual-wavelength tunable external cavity laser according to this disclosure.

At operation 405, a common resonator is provided. In some embodiments, the common resonator can be provided as a frequency tunable ring (such as certain embodiments of common resonator RING_C 301 in FIG. 3A), a non-tunable resonator, or as a multi-component resonator. The FSR of the common resonator can be designed depending on the application to have a fine or coarse granularity. The FSR of the common resonator directly translates into the available frequency offsets that can be locked between the two lasers.

At operation 410, a first resonant path is provided (for example, first resonant path 315 in FIG. 3A). The first resonant path can comprise a first optical amplifier (for example, first RSOA 325), the common resonator (for example, RING_C 301), a first resonator (for example, RING_1B 330), and a first mirror (for example MIRROR_1 336). Depending on embodiments, the first resonant path can include additional resonators (for example, RING_1A 331) in order to achieve a single non-degenerate laser frequency and first regime vernier operation across a wide gain bandwidth while simultaneously having a finely resolved frequency offset lock (small FSR for RING_C).

At operation 415, a second resonant path, comprising a second optical amplifier (for example, second RSOA_2 340), the common resonator (for example, RING_C 301), a second resonator (for example, RING_2B 335), and a second mirror (for example, MIRROR_2 336). Because the common resonator forms part of both the first resonant path and the second resonant paths, the first and second resonant paths are resonantly coupled, and thus radiate or lase, at two frequency locked frequencies.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A laser, comprising,
a common resonator, having a first free spectral range;
a first resonant path comprising a first optical amplifier, the common resonator, a second resonator having a second free spectral range, and a mirror; and
a second resonant path comprising a second optical amplifier, the common resonator, a third resonator having a third free spectral range, and a second reflective mirror,
wherein the first resonant path is resonantly coupled to the second resonant path via the common resonator,
wherein the first resonant path lases at a frequency corresponding to a coincidence between a transmission window of the common resonator and the second resonator, and
wherein the second resonant path lases at a frequency corresponding to a coincidence between a transmission window of the common resonator and the third resonator.

2. The laser of claim 1,
wherein the second resonator is frequency tunable,
wherein the first optical amplifier is a first reflective optical amplifier,
wherein the third resonator is frequency tunable, and
wherein the second optical amplifier is a second reflective optical amplifier.

3. The laser of claim 1,
wherein the common resonator is frequency tunable.

4. The laser of claim 1,
wherein the common resonator comprises a spiral waveguide, one or more tunable couplers and a phase shifter.

5. The laser of claim 1,
wherein the first resonant path further comprises:
a fourth resonator having a fourth free spectral range,
wherein the second resonant path further comprises:
a fifth resonator having a fifth free spectral range,
wherein the first resonant path lases at a frequency corresponding to a coincidence between the transmission window of the common resonator, the second resonator, and the fourth resonator, and
wherein the second resonant path lases at a frequency corresponding to a coincidence between the transmission window of the common resonator, the third resonator, and the fifth resonator.

6. The laser of claim 2, further comprising:
a multi-chip module with a first shape, wherein the first shape is divided along a boundary into a first region comprising a gain chip and a second region comprising a cavity chip,
wherein the first and second reflective optical amplifiers are provided in the first region, and
wherein the common resonator, second resonator which is frequency tunable, first mirror, third resonator which is frequency tunable, and second mirror are provided in the second region.

7. The laser of claim 6, further comprising a waveguide crossing disposed on the cavity chip, and
wherein the waveguide crossing comprises a non-interfering intersection between the first resonant path and the second resonant path.

8. The laser of claim 6, further comprising:
a first mirror with partial transmission for outputting a first laser signal from the first resonant path; and
a second mirror with partial transmission for outputting a second laser signal from the second resonant path.

9. The laser of claim 6,
wherein the first resonant path further comprises:
a fourth resonator having a fourth free spectral range, wherein the fourth resonator is frequency tunable,
wherein the second resonant path further comprises:
a fifth resonator having a fifth free spectral range, wherein the fifth resonator is frequency tunable,
wherein the first resonant path lases at a frequency corresponding to a coincidence between the transmission window of the common resonator, the second resonator, and the fourth resonator, and
wherein the second resonant path lases at a frequency corresponding to a coincidence between the transmission window of the common resonator, the third resonator, and the fifth resonator.

10. The laser of claim 6,
wherein the first mirror comprises a first tunable loop mirror provided in the second region, and
wherein the second mirror comprises a second tunable loop mirror provided in the second region.

11. A method of making a laser, comprising,
providing a common resonator, having a first free spectral range;
providing a first resonant path comprising a first optical amplifier and a second resonator having a second free spectral range; and
providing a second resonant path comprising a second optical amplifier and a third resonator having a third free spectral range,
wherein the first resonant path is resonantly coupled to the second resonant path via the common resonator,
wherein the first resonant path lases at a frequency corresponding to a coincidence between a transmission window of the common resonator and the second resonator, and
wherein the second resonant path lases at a frequency corresponding to a coincidence between a transmission window of the common resonator and the third resonator.

12. The method of claim 11,
wherein the second resonator is frequency tunable,
wherein the first optical amplifier is a first reflective optical amplifier,
wherein the third resonator is frequency tunable, and
wherein the second optical amplifier is a second reflective optical amplifier.

13. The method of claim 11,
wherein the common resonator is a frequency tunable resonator.

14. The method of claim 11,
wherein the common resonator comprises a spiral waveguide, one or more tunable couplers and a phase shifter.

15. The method of claim 11,
wherein the first resonant path further comprises:
a fourth resonator having a fourth free spectral range,
wherein the second resonant path further comprises:
a fifth resonator having a fifth free spectral range,
wherein the first resonant path lases at a frequency corresponding to a coincidence between a transmission window of the common resonator, the second resonator, and the fourth resonator, and
wherein the second resonant path lases at a frequency corresponding to a coincidence between a transmission window of the common resonator, the third resonator, and the fifth resonator.

16. The method of claim 12, further comprising:
providing a common substrate with a first shape, wherein the first shape is divided along a boundary into a first region comprising a gain chip and a second region comprising a cavity chip,
wherein the first and second reflective optical amplifiers are provided in the first region, and
wherein the common resonator, second resonator which is frequency tunable, first mirror, third resonator which is frequency tunable, and second mirror are provided in the second region.

17. The method of claim 16, further comprising a waveguide crossing disposed on the cavity chip, and
wherein the waveguide crossing comprises a non-interfering intersection between the first resonant path and the second resonant path.

18. The method of claim 16, further comprising:
providing a first mirror with partial transmission for outputting a first laser signal from the first resonant path; and
providing a second mirror with partial transmission for outputting a second laser signal from the second resonant path.

19. The method of claim 16,
wherein the first resonant path further comprises:
a fourth resonator having a fourth free spectral range,
wherein the second resonant path further comprises:
a fifth resonator having a fifth free spectral range,
wherein the first resonant path lases at a frequency corresponding to a coincidence between a transmission window of the common resonator, the second resonator, and the fourth resonator, and
wherein the second resonant path lases at a frequency corresponding to a coincidence between a transmission window of the common resonator, the third resonator, and the fifth resonator.

20. The method of claim 16,
wherein the first mirror comprises a first tunable loop mirror provided in the second region, and
wherein the second mirror comprises a second tunable loop mirror provided in the second region.
